(19) United States
(12) Patent Application Publication
(10) Pub. No.: US 2009/0021330 A1
(43) Pub. Date: Jan. 22, 2009

(54) HANDHELD TERMINAL

(75) Inventor: Takeshi TASHIRO, Shizuoka (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Toshiba Tec Kabushiki Kaisha, Tokyo (JP)

(21) Appl. No.: 12/172,471

(22) Filed: Jul. 14, 2008

(30) Foreign Application Priority Data
Jul. 19, 2007 (JP) 2007-188184

(51) Int. Cl. H03H 2/00

(52) U.S. Cl. 333/24 R

(57) ABSTRACT

A first unit and a second unit are connected rotatably by a hinge. A first coil and a second coil for performing communication between the first unit and the second unit by facing each other are arranged at the first unit and the second unit, respectively. A movable body is provided at the second unit. The movable body projects from the second unit due to elastic force arid is adapted to displace toward a failing direction against the elastic force by contacting with the first unit during a process of opening of the first unit with respect to the second unit. The second coil is located at the movable body, and the first coil is located at a portion of the first unit that is contacted by the movable body during the process of opening the first unit with respect to the second unit.

### CROSS REFERENCE TO RELATED APPLICATION

The present application is based on arid claims the benefit of priority of Japanese Patent Application No. 2007-188184 filed on Jul. 19, 2007, the entire contents of which are incorporated herein by reference.

### BACKGROUND OF THE INVENTION

1. Field of the Invention

The present invention relates to a clamshell handheld terminal.

2. Discussion of the Background

A handheld terminal is used in restaurants and so on for managing customer's order information and so on. A clamshell handheld terminal is an example of the handheld terminal. The clamshell handheld terminal is comprised of two units, which are connected by a hinge. Generally, both of the units are able to communicate data with each other. Generally, both of the units are electrically connected via a flexible cable over the hinge.

Japanese Laid-Open Publication No. 2006-228075 discloses a handheld terminal that has electromagnetic induction coils for contributing radio communication by electromagnetic induction, along the path of the flexible cable. The electromagnetic coils are arranged in series with the flexible cable. Data communication between the units is executed via the flexible cable and the electromagnetic coils. This conventional handheld terminal uses a flexible cable for connecting both of the units over the hinge. Therefore, the flexible cable bends in association with an opening-and-closing motion of both of the units. Thus, the conventional handheld terminal has a problem that the flexible cable is easily broken by repetitive opening-and-closing motions of both of the units.

### SUMMARY OF THE INVENTION

It is one object of the present invention to provide a clamshell handheld terminal that is quite resistant to disconnection caused by repetitive opening-and-closing motions.

According to the present invention, a handheld terminal includes a first unit including a first circuit for executing radio communication by electromagnetic induction with electric power, and a first functional face for performing a function according to the first circuit; a second unit including a second circuit for executing radio communication powered by electromagnetic induction from the first circuit, and a second functional face for performing a function according to the second circuit; a hinge for connecting the first unit and the second unit rotatably such that the first unit and the second unit are movable between a closed state in which the first functional face and the second functional face face each other and an opened state in which the first functional face and the second functional face are adjoining, wherein a first end face of the first unit faces a second end face of the second unit in the opened state; a movable body arranged at one of the first end face and the second end face, wherein the movable body projects from said one of the first end face and the second end face due to elastic force, and the movable body is displaced toward a falling direction against the elastic force by contacting with a contacted portion of the other one of the first end face and the second end face when the first unit and the second unit move from the closed state to the opened state; and an antenna for performing the radio communication; wherein the antenna comprises: a first coil for contributing electromagnetic induction, which is located at one of the movable body and the contacted portion, and which is connected to the first circuit, and a second coil for contributing electromagnetic induction, which is located at the other one of the movable body and the contacted portion, and which is connected to the second circuit, and wherein the second coil is coupled electromagnetically with the first coil when the movable body and the contacted portion are contacted with each other.

### BRIEF DESCRIPTION OF THE DRAWINGS

A more complete appreciation of the present invention and many of the attendant advantages thereof will be readily obtained as the same becomes better understood by reference to the following detailed description when considered in connection with the accompanying drawings, wherein:

FIG. 1 is a perspective view showing a closed handheld terminal according to an embodiment of the present invention;

FIG. 2 is a perspective view showing an opened handheld terminal according to an embodiment of the present invention;

FIG. 3 is an exploded perspective view of a movable body according to an embodiment of tie present invention;

FIG. 4 is a side view of a handheld terminal according to an embodiment of the present invention, a part of which is cross-sectional;

FIG. 5 is a side view showing an intermediate condition in the process of the transition from a closed state to a fully opened state of a handheld terminal according to an embodiment of the present invention, a part of which is cross-sectional;

FIG. 6 is a side view showing a fully opened state of a handheld terminal according to an embodiment of the present invention, a part of which is cross-sectional;

FIG. 7 is a side view of a handheld terminal according to another embodiment of the present invention, a part of which is cross-sectional;

FIG. 8 is a side view of a handheld terminal according to another embodiment of the present invention, a part of which is cross-sectional;

FIG. 9 is a side view of a handheld terminal according to another embodiment of the present invention, a part of which is cross-sectional; and

FIG. 10 is a side view of a handheld terminal according to another embodiment of the present invention, a part of which is cross-sectional.

### DETAILED DESCRIPTION OF THE INVENTION

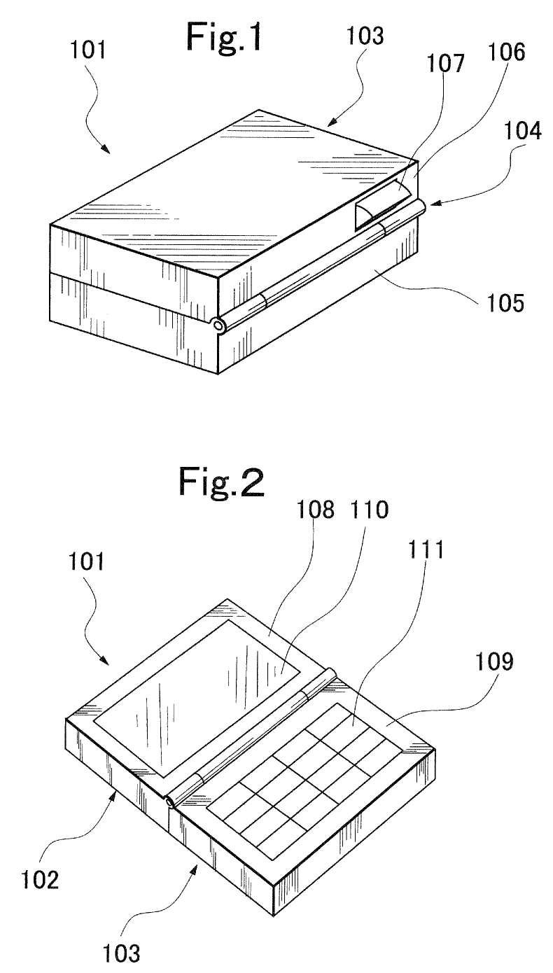

An embodiment of a handheld terminal according to the present invention is described below with reference to FIGS. 1 through 6.

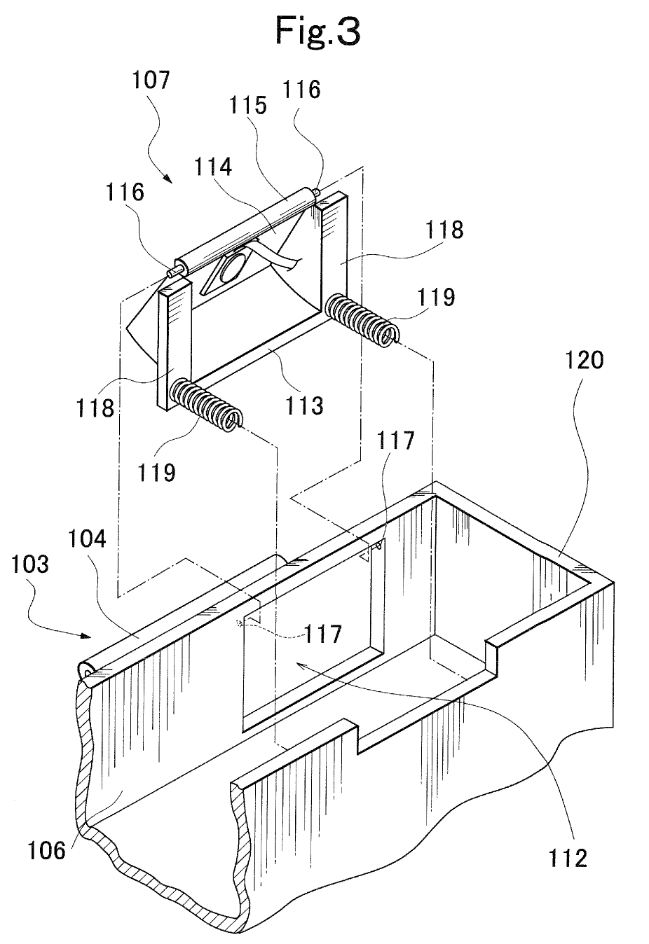

As shown in FIG. 1, a handheld terminal 101 includes a first unit 102, a second unit 103, and a hinge 104 connecting the first unit 102 and the second unit 103 rotatably. The handheld terminal 101 is portable. The first unit 102 and the second unit 103 have a first end face 105 and a second end face 106, respectively. The hinge 104 is disposed at the first end face 105 and the second end face 106. A movable body 107 is arranged on the second end face 106 and is capable of rising due to elastic force falling against the elastic force. The movable body 107 will hereinafter be described in detail with reference to FIG. 3.

As shown in FIG. 2, a first functional face 108 and a second functional face 109 are provided on the first unit 102 and the second unit 103, respectively, so as to appear when the handheld terminal 101 is opened. The first functional face 108 and the second functional face 109 face each other when the handheld terminal 101 is closed. The hinge 104 connects the units 102 and 103 such that the first unit 102 and the second unit 103 are movable between a closed state and an opened state. In the closed state, the first functional face 108 and the second functional face 109 face each other. In the opened state, the first functional face 108 and the second functional face 109 are adjoining. In the opened state, the first end face 105 and the second end face 106 are facing. A liquid crystal panel 110 including a touch panel (not shown in Figures) is arranged at the first functional face 108. A keyboard 111 is arranged at the second functional face 109.

FIG. 3 is an exploded perspective view of the movable body 107. As shown in FIG. 3, a rectangular notch 112 is formed in the second end face 106. The movable body 107 is attached to the notch 112. The movable body 107 is shaped like a wedge-shaped cylinder, which has a hollow construction. The movable body 107 has an opening formed at a side face that is not curved face, and an antenna mounting face 114 formed at an another side face that is not a curved face. A rotating part 115, which is shaped like a circular cylinder, is disposed at an edge forming an apex of the wedge-shaped shape. A pair of projections 116 jut from respective ends of the rotating part 115. A pair of holes 117 for attaching the projections 1.16 are disposed at the inner sides of the notch 112. The holes 117 are disposed at respective lateral sides of the notch 112, situated near the hinge 104. The movable body 107 is rotatably attached to the notch 112, by fitting the projections 116 to the corresponding holes 117. In the situation that the movable body 107 is attached to the notch 112, the opening face 113 faces to inner side of the second unit 103, while the antenna mounting face 114 faces to outer side of the second unit 103. The movable body 107 has a pair of retaining boards 118 corresponding to the position of the opening face 113. The retaining boards 118 extend from the opening face 113 in opposite directions from each other and in parallel to an axis of the rotating part 115. Therefore, the retaining boards 118 contact with the inside face of the second end face 106, in the process of external rotation of the movable body 107. Thus, as the external rotation of the movable body 107 is restricted by the retaining boards 118, the movable body 107 is arranged swingably in a predetermined range, with a swing axis arranged at a side near the hinge.

A pair of springs 119 is attached to the retaining boards 118, respectively. Inside the second unit 103, a spring mounting wall 120 is disposed parallel to the second end face 106. One end of each spring 119 is connected to the corresponding retaining board 118, while the other end is connected to the spring mounting wall 120. The retaining boards 118 are pressured by the springs 119, in a direction away from the spring mounting wall 120. Therefore, the movable body 107 is urged in an external direction of the second unit 103 from the notch 112.

Next, an internal structure of the handheld terminal 101 is described below.

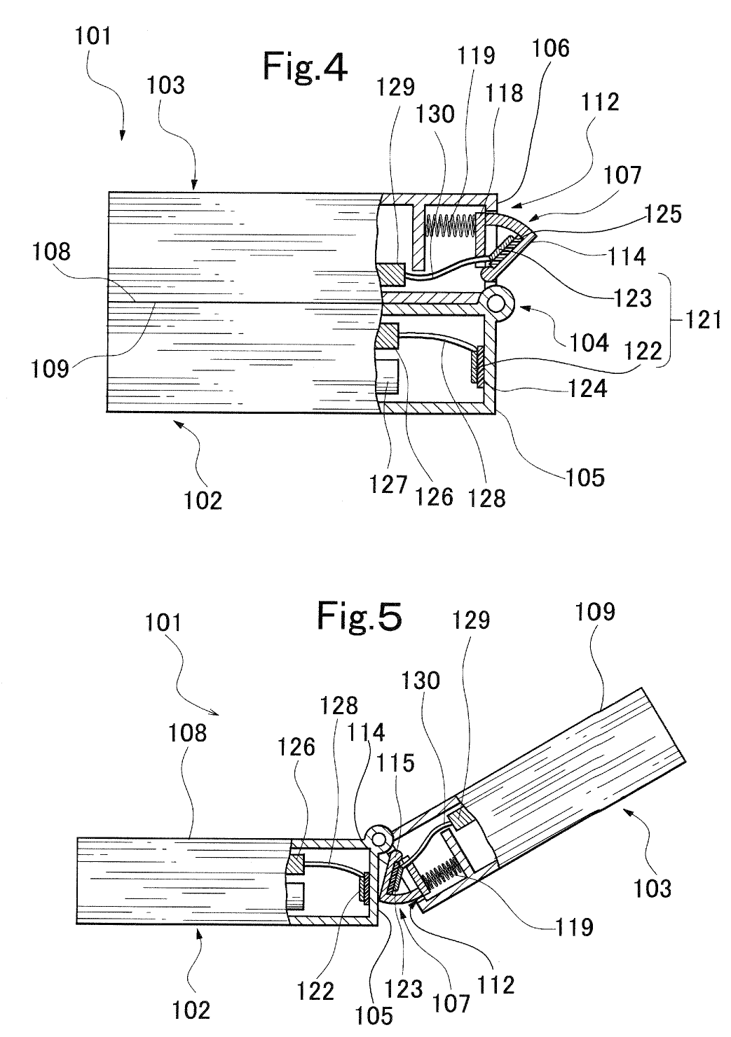

As shown in FIG. 4, the handheld terminal 101 has an antenna 121 for contributing radio communication between the first unit 102 and the second unit 103, by electromagnetic induction. The first unit 102 incorporates a first coil 122 for contributing electromagnetic induction. The second unit 103 incorporates a second coil 123 for contributing electromagnetic induction. The antenna 121 is comprised of the first coil 122 and the second coil 123.

The first coil 122 is attached to the inside face of the first end face 105, via a first substrate 124. The second coil 123 is attached to the inside face of the antenna mounting face 114, via a second substrate 125. The portion where the first coil 122 is disposed is a contacted portion where the antenna mounting face 114 contacts, in a process of the transition of the state of the handheld terminal 101 from the closed state to the opened state. The first coil 122 and the second coil 123 are positioned so as to be able to couple electromagnetically by facing each other, in the state that the first unit 102 and the second unit 103 are opened.

The first unit 102 incorporates a first circuit. The first circuit includes a first circuit board 126, and a battery pack 127 as a power circuit for feeding power to the first circuit board 126. The first circuit board 126 is connected to the first substrate 124 via a cable 128. The first functional face 108 including the liquid crystal panel 110 performs a function according to the first circuit. More specifically, the first circuit board 126 controls the liquid crystal panel 110 and the touch panel and processes the information input from the touch panel.

The second unit 103 incorporates a second circuit. The second circuit includes a second circuit board 129. The second circuit board 129 is connected to the second substrate 125 via a flexible cable 130. The second functional face 109 including the keyboard 111 performs a function according to the second circuit. More specifically, the second circuit board 129 processes the information input from the keyboard 111.

Thus, the first circuit board 126 and the second circuit board 129 execute radio communication with each other by the electromagnetic induction, which is contributed by the first coil 122 and the second coil 123.

In operation, as shown in FIG. 4, when the handheld terminal 101 is closed, the movable body 107 projects from the notch 112 because the movable body 107 is urged by the springs 119. Swinging of the movable body 107 in the projecting direction is restricted because the retaining boards 118 are contacting with the inside face of the second end face 106. In this state, the first coil 122 and the second coil 123 are not positioned to be capable of coupling electromagnetically, because the first end face 105 and the antenna mounting face 114 are not closely-situated each other.

As shown in FIG. 5, by opening the first unit 102 and the second unit 103, the second unit 103 rotates about the hinge 104, against the first unit 102. Then, at a certain point, the first end face 105 and the antenna mounting face 114 contact with each other. In the process of the transition from the closed state to the point that the first end face 105 and the antenna mounting face 114 contact with each other, the movable body 107 is not pressured from out side of the second unit 103. In the process until this point, the projecting configuration of the movable body 107 does not change because the movable body 107 is urged by the springs 119 in the projecting direction. In fact, the flexible cable 130 does not bend in the process until this point. When the antenna mounting face 114 of the movable body 107 and the contacted portion of the first end face 105 are contacting with each other, the first coil 122 and the second coil 123 are close enough to couple electromagnetically. In this state, the second coil 123 generates induced electromotive force induced by the magnetic flux generated by the first coil 122. The second circuit board 129 is powered by the induced electromotive force. The second circuit is powered by the electromagnetic induction from the first circuit.

If information is input from the keyboard 111 disposed at the second functional face 109 in this state, a signal according to -the input information is processed by the second circuit board 129. Then, the signal is output to the coil 123 via the flexible cable 130. Following this, the signal is transmitted from the second coil 123 to the first coil 122 by electromagnetic induction. Then, the signal is received by the first circuit board 126 via the cable 128. The first circuit board 126 controls the liquid crystal panel 110 and the touch panel arranged at the first functional face 108, on the basis of the signal. When the first circuit and the second circuit are capable of communication, the powered second circuit board 129 constantly outputs a signal indicating the condition that the first circuit and the second circuit are capable of communication to the second coil 123, regardless of presence or absence of the input from the keyboard 111. The first circuit board 126 executes a processing to indicate that the first unit 102 and the second unit 103 are capable of communication, on the liquid crystal panel 110.

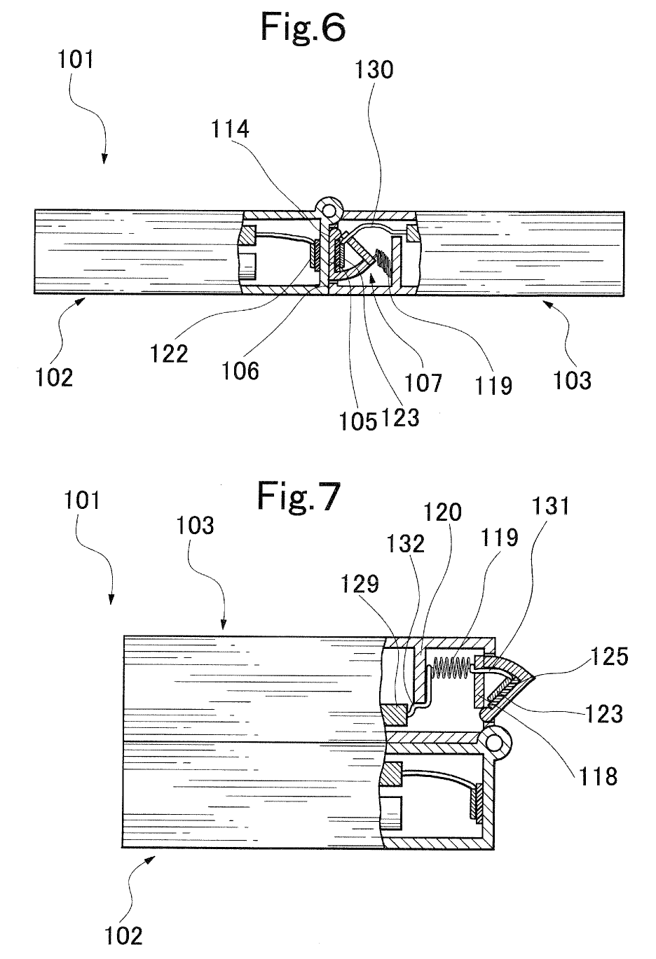

If the second unit 103 rotates and opens against the first unit 102 even further from the certain point shown in FIG. 5, the contacted portion on the first end face 105 presses the antenna mounting face 114. Then, the movable body 107 displaces toward the falling direction into the second unit 103, by swinging with the rotating part 115 as the central axis of the rotation. As shown in FIG. 6, the first unit 102 and the second unit 103 are able to be opened until the first end face 105 contacts with the second end face 106 at a maximum. In the state that the first unit 102 and the second unit 103 are opened at a maximum, the first end face 106 and the antenna mounting face 114 are disposed in the same plane. The flexible cable 130 bends slightly, in association with the falling of the movable body 107 into the second unit 103. This bending curvature is alleviated with respect to the bending curvature according to the conventional handheld terminal. The first end face 105 and the antenna mounting face 114 are contacting with pressure while the movable body 107 falls, because the movable body 107 is urged in the projecting portion by the springs 119. Thus, in the process of transition of the handheld terminal 101 from the state shown in FIG. 5 to the state shown in FIG. 6, the first coil 122 and the second coil 123 continue coupling electromagnetically constantly, therefore, the communication between the first unit 102 and the second unit 103 works stably.

With the handheld terminal 101 according to this embodiment of the present invention, it is possible to alleviate physical load on the cables associated with the opening-and-closing motion of the first unit 102 and the second unit 103. It is possible to indicate that the first unit 102 and the second unit 103 are capable of communication, on the liquid crystal panel 110.

As a modification of the embodiment described above, a variety of elastic members, such as a blade spring or a rubber ball, may be adopted in place of the springs 119.

Other embodiments of the handheld terminal 101 according to the present invention are described below with reference to FIGS. 7 through 10. In these embodiments, reference numerals used in the previous embodiment described with reference to FIGS. 1 through 6 will be used to designate the same elements, and the overlapping explanation will be omitted.

In the embodiment shown in FIG. 7, the handheld terminal 101 includes a conductive spring 119, which connects the second coil 123 and the circuit board 129 electrically. The movable body 107 is supported with elastic force by the conductive spring 119, in the same way as the previous embodiment described above. In contrast to the previous embodiment, the conductive spring 119 is adapted to conduct electricity between the second coil 123 and the circuit board 129. A cable 131 and a cable 132 are adopted in this embodiment, in place of the flexible cable 130. The cable 131 extends from the second substrate 125 to one end of the conductive spring 119 near the retaining board 118. The cable 132 extends from the second circuit board 129 to another end of the conductive spring 119 near the spring mounting wall 120. Thus, the second coil 123 and the second circuit board 129 are connected electrically via the cable 131, conductive spring 119, and the cable 132. With the handheld terminal 101 according to this embodiment of the present invention, the cable 131 and the cable 132 do not bend in association with the swinging of the movable body 107. The conductive spring 119 is the only component part that bends in association with the swinging of the movable body 107. The conductive spring 119 has durability against bending curvature, higher than that of a flexible cable. Therefore, it is possible to enhance the resistance of the handheld terminal 101 dramatically against disconnection caused by repetitive opening-and-closing motions of the handheld terminal 101. In addition, a variety of conductive elastic members can be adopted in place of the conductive spring 119.

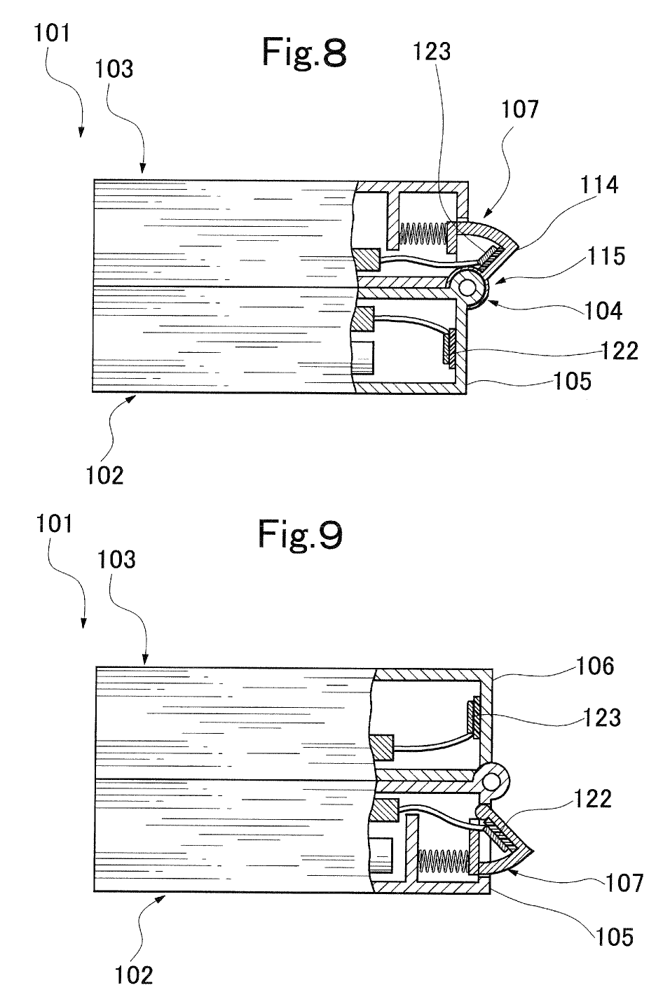

In the embodiment shown in FIG. 8, the rotating part 115 of the movable body 107 is unified with the hinge 104. The movable body 107 is arranged swingably with the hinge 104 as the central axis of the rotation. With the handheld terminal 101 according to this embodiment of the present invention, the first end face 105 and the antenna mounting face 114 are in close contact with each other, while the first end face 1.05 is contacting with the antenna mounting face 114. In the state that the first end face 105 and the antenna mounting face 114 are in close contact with each other, the first coil 122 and the second coil 123 couple electromagnetically, rigidly. Therefore, it is possible to enhance the stability of the communication between the first unit 102 and the second unit 103.

In the embodiment shown in FIG. 9, the movable body 107 is not arranged on the second end face 106 of the second unit 103, but is arranged on the first end face 105 of the first unit 102, and is capable of rising due to elastic force and falling against the elastic force. The first coil 122 is located at the movable body 107. The second coil 123 is disposed at a contacted portion where the movable body 107 contacts in the process of the transition of the first unit 102 and the second unit 103 from the closed state to the opened state. The movable body 101 displaces toward a falling direction by contacting with the contacted portion of the second end face 106 in a process of the transition of the states of the first unit 102 arid the second unit 103, from the closed state to the opened state.

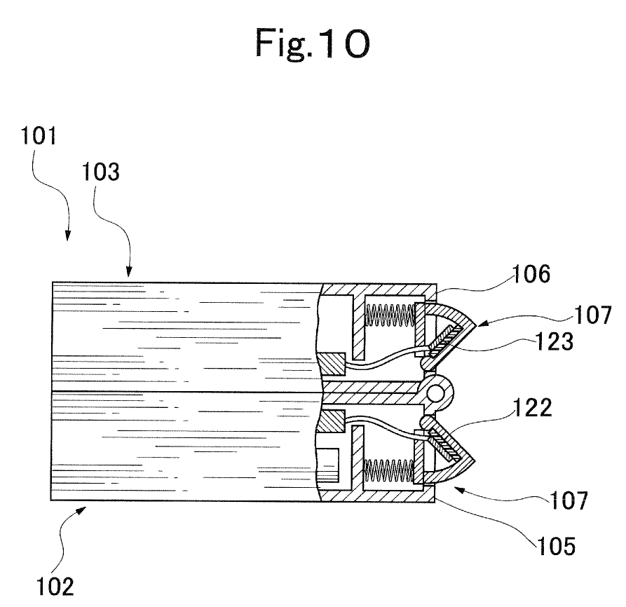

In the embodiment shown in FIG. 10, movable bodies 107 are arranged at respective sides of the first end face 105 and the second end face 106. The movable bodies 107 are located in positions such that they contact each other in the process of the transition of the first unit 102 and the second unit 103 from the closed state to the opened state.

Yet still further, the antenna 121 according to the present embodiment can be adapted to a variety of devices or instruments having a clamshell structure.

Obviously, numerous modifications and variations of the present invention are possible in light of the above teachings. It is therefore to be understood that within the scope of the appended claims, the invention may be practiced otherwise than as specifically described herein.

What is claimed is:

1. A handheld terminal, comprising:
a first unit including a first circuit for executing radio communication by electromagnetic induction with electric power, and a first functional face for performing a function according to the first circuit;
a second unit including a second circuit for executing radio communication powered by electromagnetic induction from the first circuit, and a second functional face for performing a function according to the second circuit;
a hinge for connecting the first unit and the second unit rotatably such that the first unit and the second unit are movable between a closed state in which the first functional face and the second functional face face each other and an opened state in which the first functional face and the second functional face are adjoining, wherein a first end face of the first unit faces a second end face of the second unit in the opened state;
a movable body arranged at one of the first end face and the second end face, wherein the movable body projects from said one of the first end face and the second end face due to elastic force, and the movable body is displaced toward a falling direction against the elastic force by contacting with a contacted portion of the other one of the first end face and the second end face when the first unit and the second unit move from the closed state to the opened state; and
an antenna for performing the radio communication;
wherein the antenna comprises:
a first coil for contributing electromagnetic induction, which is located at one of the movable body and the contacted portion, and which is connected to the first circuit, and
a second coil for contributing electromagnetic induction, which is located at the other one of the movable body and the contacted portion, and which is connected to the second circuit, and
wherein the second coil is coupled electromagnetically with the first coil when the movable body and the contacted portion are contacted with each other.

2. A handheld terminal according to claim 1,
wherein the movable body has a first side near the hinge and a second side away from the hinge; and
wherein the movable body is rotatable about an axis arranged at the first side.

3. A handheld terminal according to claim 1,
wherein the elastic force is provided to the movable body by a conductive elastic member; and
wherein the conductive elastic member conducts electrical energy to the one of the first coil and the second coil that is located at the movable body.

4. A handheld terminal according to claim 1, wherein the handheld terminal indicates that the first circuit and the second circuit are capable of communication, when the first circuit and the second circuit are capable of communication.

5. A handheld terminal, comprising:
a first unit including a first circuit for executing radio communication by electromagnetic induction with electric power, and a first functional face for performing a function according to the first circuit;
a second unit including a second circuit for executing radio communication powered by electromagnetic induction from the first circuit, and a second functional face for performing a function according to the second circuit;
a hinge for connecting the first unit and the second unit rotatably such that the first unit arid the second unit are movable between a closed state in which the first functional face and the second functional face face each other and an opened state in which the first functional face and the second functional face are adjoining, wherein a first end face of the first unit faces a second end face of the second unit in the opened state;
a first movable body, which is arranged at the first end face, and which projects from the first end face due to elastic force;
a second movable body, which is arranged at the second end face arid which projects from the second end face due to elastic force, wherein each of the first movable body and the second movable body is displaced toward a falling direction against the elastic force by contacting each other when the first unit and the second unit move from the closed state to the opened state; and
an antenna for performing the radio communication;
wherein the antenna comprises:
a first coil for contributing electromagnetic induction, which is located at the first movable body, and which is connected to the first circuit, and
a second coil for contributing electromagnetic induction, which is located at the second movable body, arid which is connected to the second circuit, and
wherein the second coil is coupled electromagnetically with the first coil when the first movable body arid the second movable body are contacted with each other.

6. A handheld terminal according to claim 5, wherein the handheld terminal indicates that the first circuit and the second circuit are capable of communication, when the first circuit and the second circuit are capable of communication.
